(19) United States
(12) Patent Application Publication
(10) Pub. No.: US 2012/0276349 A1
(43) Pub. Date: Nov. 1, 2012

(54) ANTI-CORROSION TREATMENT PROCESS FOR ALUMINUM OR ALUMINUM ALLOY AND ALUMINUM OR ALUMINUM ALLOY ARTICLE THEREOF

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); NAN MA, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/176,354

(22) Filed: Jul. 5, 2011

(30) Foreign Application Priority Data
Apr. 28, 2011 (CN) 201110108132.2

(51) Int. Cl. B32B 15/04; C23C 14/35; B32B 27/06; B32B 3/10; B32B 5/00; B32B 9/04

(52) U.S. Cl. 428/209; 428/472; 428/472.2; 428/336; 428/446; 428/422; 204/192.15

(57) ABSTRACT

An aluminum or aluminum alloy article is described. The aluminum or aluminum alloy article includes an aluminum or aluminum alloy substrate, a barrier layer formed on the substrate, a color layer formed on the barrier layer, and an insulation layer formed on the color layer. The barrier layer and the color layer are formed by vacuum sputtering. The barrier layer is a layer of chromium-oxygen-nitrogen, aluminum-oxygen-nitrogen, or titanium-oxygen-nitrogen. The insulation layer is an external layer of the aluminum or aluminum alloy article.

### CROSS-REFERENCE TO RELATED APPLICATIONS

This application is one of the three related co-pending U.S. patent applications listed below. All listed applications have the same assignee. The disclosure of each of the listed applications is incorporated by reference into the other listed applications.

| Attorney | | |
|---|---|---|
| Docket | | |
| No. | Title | Inventors |
| US 35689 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |
| US 35696 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |
| US 38618 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |

### BACKGROUND

1. Technical Field

The present disclosure relates to an anti-corrosion treatment process for aluminum or aluminum alloy and aluminum or aluminum alloy article thereof.

2. Description of Related Art

Aluminum or aluminum alloy is widely used for its excellent properties. However, the aluminum or aluminum alloy is prone to corrosion because the aluminum or aluminum alloy has a very low standard electrode potential. To protect the aluminum or aluminum alloy from corrosion, an insulation layer may be formed between the aluminum or aluminum alloy and a vacuum deposited protective layer for the purpose of preventing a galvanic corrosion from forming in the layers and the aluminum or aluminum alloy. However, since the layers almost have pinholes and cracks formed therein, the corrosives can permeate the layers create a galvanic cell in the protective layer and the aluminum or aluminum alloy. The protective layer may become a cathode of the galvanic cell and the aluminum or aluminum alloy may become an anode of the galvanic cell. For a surface area of the cathode that larger than the surface area of the anode (small portion surface of the aluminum or aluminum alloy), a large corrosion current of the galvanic cell will be created in the protective layer and the aluminum or aluminum alloy. As such, the protective layer and the aluminum or aluminum alloy are quickly corroded.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of an aluminum or aluminum alloy article.

FIG. 2 is an overlook view of an exemplary embodiment of a vacuum sputtering device.

### DETAILED DESCRIPTION

According to an exemplary embodiment, an anti-corrosion treatment process for aluminum or aluminum alloy may include the following steps:

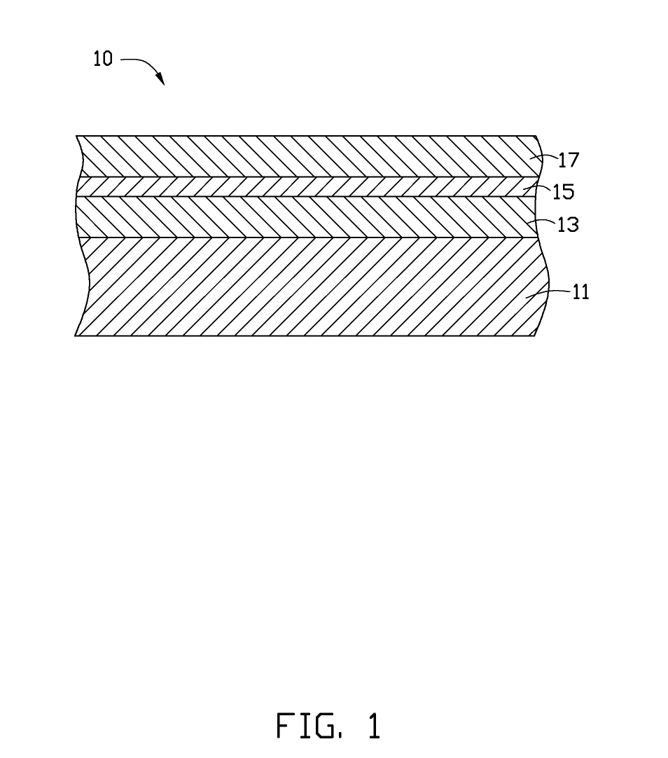

Referring to FIG. 1, an aluminum or aluminum alloy substrate 11 is provided. The substrate 11 is then pre-treated, such a pre-treating process may include the following steps:

The substrate 11 is cleaned in an ultrasonic cleaning device (not shown) filled with ethanol or acetone.

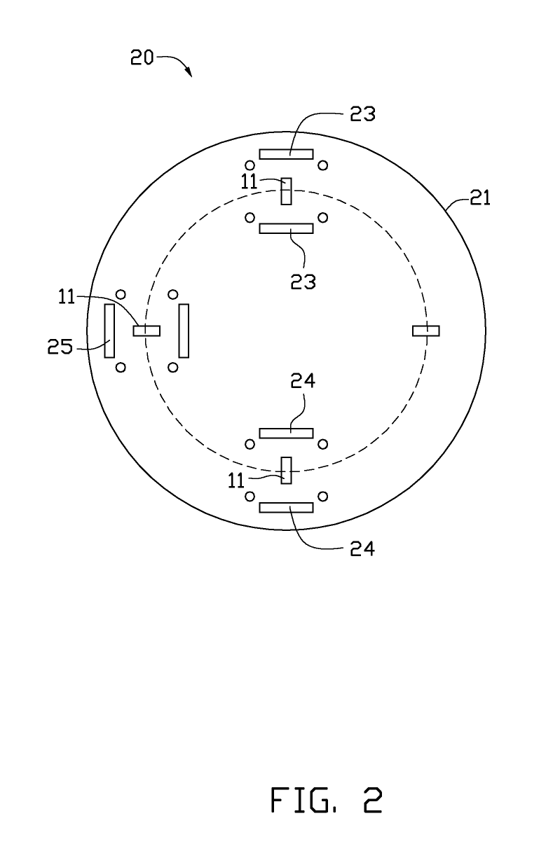

The substrate 11 is plasma cleaned. Referring to FIG. 2, the substrate 11 may be positioned in a coating chamber 21 of a vacuum sputtering device 20. First targets 23, second targets 24, and third targets 25 are is fixed in the coating chamber 21. The first target 23 may be a target of chromium, aluminum, or titanium. The second target 24 may be a target of chromium. The third target 25 may be a target of silicon or aluminum.

The coating chamber 21 is then evacuated to about 8.0×10⁻³ Pa. Argon gas having a purity of about 99.999% may be used as a working gas and is injected into the coating chamber 21 at a flow rate of about 500 standard-state cubic centimeters per minute (sccm). The substrate 11 have a negative bias voltage of about −500 V to about −800 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 5 minutes (min) to 10 min. The plasma cleaning process enhances the bond between the substrate 11 and the subsequent layers. The targets there are unaffected by the pre-cleaning process.

A barrier layer 13 may be magnetron sputtered on the pretreated substrate 11 by using the first targets 23. Magnetron sputtering of the barrier layer 13 is implemented in the coating chamber 21. The inside of the coating chamber 21 may be heated to about 100° C.-250° C. Nitrogen (N₂) and oxygen (O₂) may be used as reaction gases and are injected into the coating chamber 21 at a flow rate of about 30 sccm-60 sccm and 40 sccm-80 sccm respectively, and argon gas may be used as a working gas and is injected into the coating chamber 21 at a flow rate of about 100 sccm-200 sccm. A power of 5 kilowatt (KW)-15 KW is applied to the first targets 23, then chromium, aluminum, or titanium atoms are sputtered off from the first targets 23. The chromium, aluminum, or titanium atoms, and nitrogen and oxygen atoms are then to be ionized in an electrical field in the coating chamber 21. The ionized chromium, aluminum, or titanium chemically reacts with the ionized nitrogen and oxygen to deposit the barrier layer 13 on the substrate 11. During the depositing process, the substrate 11 may have a negative bias voltage of about −100 V to about −300 V. Depositing of the barrier layer 13 may take about 30 min-120 min.

The barrier layer 13 is a layer of chromium-oxygen-nitrogen (CrON), aluminum-oxygen-nitrogen (AlON), or titanium-oxygen-nitrogen (TiON). The barrier layer 13 has Cr—O and Cr—N crystalline grains, Al—O and Al—N crystalline grains, or Ti—O and Ti—N crystalline grains formed therein. The thickness of the barrier layer 13 may be about 100 nm-600 nm.

During the depositing of the barrier layer 13, Cr—O and Cr—N crystalline grains, Al—O and Al—N crystalline grains, or Ti—O and Ti—N crystalline grains will form simultaneously. Each kind of crystalline grains inhibit the growth of the other kind of crystalline grains, as such, the size of the crystalline grains is reduced, which provides the barrier layer 13 a high density.

A color layer 15 may be magnetron sputtered on the barrier layer 13 by using the second targets 24. Magnetron sputtering of the color layer 15 is implemented in the coating chamber 21. The internal temperature of the coating chamber 21 may be of about 50° C.-150° C. Nitrogen (N₂) may be used as a reaction gas and is injected into the coating chamber 21 at a flow rate of about 10 sccm-120 sccm, and argon gas may be used as a working gas and is injected into the coating chamber 21 at a flow rate of about 100 sccm-200 sccm. A power of 5 kilowatt (KW)-10 KW is applied to the second targets 24, then chromium atoms are sputtered off from the second targets 24. The chromium atoms and nitrogen atoms are then to be ionized in an electrical field in the coating chamber 21. The ionized chromium then chemically reacts with the ionized nitrogen to deposit the color layer 15 of chromium nitride (CrN) on the barrier layer 13. During the depositing process, the substrate 11 may have a negative bias voltage of about −100 V to about −300 V. Depositing of the color layer 15 may take about 10 min-30 min.

The color layer 15 is a layer of chromium nitride (CrN). The color layer 15 has a thickness of about 200 nm-400 nm.

An insulation layer 17 may be sputtered on the color layer 15 by using the third targets 25. Sputtering of the insulation layer 17 is implemented in the coating chamber 21. The internal temperature of the coating chamber 21 may be of about 150° C.-250° C. Oxygen (O₂) may be used as a reaction gas and is injected into the coating chamber 21 at a flow rate of about 100 sccm-200 sccm, and argon gas may be used as a working gas and is injected into the coating chamber 21 at a flow rate of about 100 sccm-150 sccm. A power at a level of 5 kilowatt (KW)-15 KW is applied to the third targets 25, then silicon or aluminum atoms are sputtered off from the third targets 25. The silicon or aluminum atoms, and oxygen atoms are then to be ionized in an electrical field in the coating chamber 21. The ionized silicon or aluminum then chemically reacts with the ionized oxygen to deposit the insulation layer 17 on the color layer 15. During the depositing process, the substrate 11 may be biased with a negative bias voltage of about −100 V to about −300 V. Depositing of the insulation layer 17 may take about 60 min-120 min.

The insulation layer 17 is a transparent layer of silicon dioxide (SiO₂) or aluminum oxide (Al₂O₃). The insulation layer 17 has a thickness of about 200 nm-400 nm.

It is to be understood that, the barrier layer 13 and the silicon dioxide or aluminum oxide layer can also be formed by arc ion plating or evaporation deposition.

It is to be understood that the color layer 15 can also be a layer of titanium-carbon-nitrogen (TiCN), titanium nitride (TiN), chromium-carbon-nitrogen (CrCN), or any other decorative layers formed by vacuum sputtering or arc ion plating.

It is to be understood that the insulation layer 17 can also be a layer of polytetrafluoroethylene formed by chemical vacuum deposition or spraying, or a layer of insulative paint or insulative ink formed by spraying or printing.

FIG. 1 shows an aluminum or aluminum alloy article 10 formed by the exemplary method. The aluminum or aluminum alloy article 10 includes the aluminum or aluminum alloy substrate 11, the barrier layer 13 formed on a surface of the substrate 11, the color layer 15 formed on the barrier layer 13, and the insulation layer 17 formed on the color layer 15.

In the exemplary embodiment, the insulation layer 17 is the outermost layer. The insulation layer 17 blocks most corrosives, so only a small amount of the corrosives may enter through the pinholes or cracks that may have been formed in the color layer 15 and transit to a small portion surface of the substrate 11. Thus even if a galvanic cell is created in the color layer 15 and the substrate 11, the color layer 15, namely the cathode, has a very small surface area and may be proportional to the anode surface area (the small portion surface of the substrate 11), then the corrosion current of the galvanic cell is very small and the corroding of the color layer 15 and the substrate 11 is greatly reduced. Moreover, the barrier layer 13 has a high density to further block the corrosives from transiting to the substrate 11 and reduces the concentration of the corrosives arrived at the substrate 11, which further reduces the corroding in the aluminum or aluminum alloy article 10. As such, the excellent corrosion resistance property of the aluminum or aluminum alloy article 10 is achieved.

Additionally, the insulation layer 17 is transparent, which will not affect the decoration of the color layer 15 for the aluminum or aluminum alloy article 10.

It is to be understood that, the insulation layer 17 can also be opaque if a decorative appearance is not requested.

A salt spray test has been performed on the aluminum or aluminum alloy articles 10. The salt spray test uses a sodium chloride (NaCl) solution having a mass concentration of 5% at a temperature of 35° C. The test indicates that the corrosion resistance property of the aluminum or aluminum alloy article 10 lasts more than 96 hours, thus, the aluminum or aluminum alloy article 10 has an excellent corrosion resistance property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. An aluminum or aluminum alloy article, comprising:
an aluminum or aluminum alloy substrate;
a barrier layer formed on the substrate by vacuum sputtering, the barrier layer being a layer of chromium-oxygen-nitrogen, aluminum-oxygen-nitrogen, or titanium-oxygen-nitrogen;
a color layer formed on the barrier layer by vacuum sputtering; and
an insulation layer formed on the color layer, the insulation layer being an external layer of the aluminum or aluminum alloy article.

2. The aluminum or aluminum alloy article as claimed in claim 1, wherein the barrier layer has a thickness of about 100 nm-600 nm.

3. The aluminum or aluminum alloy article as claimed in claim 1, wherein the color layer is a layer of chromium nitride and has a thickness of about 200 nm-400 nm.

4. The aluminum or aluminum alloy article as claimed in claim 1, wherein the color layer is a layer of titanium-carbon-nitrogen, titanium nitride, or chromium-carbon-nitrogen formed by vacuum sputtering or arc ion plating.

5. The aluminum or aluminum alloy article as claimed in claim 1, wherein the insulation layer is a layer of silicon dioxide or aluminum oxide formed by vacuum sputtering, arc ion plating, or evaporation deposition.

6. The aluminum or aluminum alloy article as claimed in claim 5, wherein the silicon dioxide or aluminum oxide layer has a thickness of about 200 nm-400 nm.

7. The aluminum or aluminum alloy article as claimed in claim 1, wherein the insulation layer is a layer of polytetrafluoroethylene formed by chemical vacuum deposition or spraying.

8. The aluminum or aluminum alloy article as claimed in claim 1, wherein the insulation layer is a layer of insulative paint or insulative ink formed by spraying or printing.

9. An anti-corrosion treatment process for aluminum or aluminum alloy, comprising:
providing an aluminum or aluminum alloy substrate;
forming a barrier layer on the substrate by vacuum sputtering, using chromium, aluminum, or titanium target, using nitrogen and oxygen as reaction gases; the barrier layer being a layer of chromium-oxygen-nitrogen, aluminum-oxygen-nitrogen, or titanium-oxygen-nitrogen;
forming a color layer on the barrier layer by vacuum sputtering; and
forming an insulation layer on the color layer, the insulation layer being an external layer.

10. The process as claimed in claim 9, wherein; forming the barrier layer is by using a magnetron sputtering process, the target is applied with a power of about 5 KW-15 KW; the nitrogen has a flow rate of about 30 sccm-60 sccm, the oxygen has a flow rate of about 40 sccm-80 sccm; uses argon as a working gas, the argon has a flow rate of about 100 sccm-200 sccm; magnetron sputtering of the barrier layer is conducted at a temperature of about 100° C.-250° C. and takes about 30 min-120 min.

11. The process as claimed in claim 10, wherein the substrate has a negative bias voltage of about −100V to about −300V during sputtering the barrier layer.

12. The process as claimed in claim 9, wherein the color layer is a layer of chromium nitride, forming the color layer is by using a magnetron sputtering process, uses chromium target, the target is applied with a power of about 5 KW-10 KW; uses nitrogen as a reaction gas, the nitrogen has a flow rate of about 10 sccm-120 sccm; uses argon as a working gas, the argon has a flow rate of about 100 sccm-200 sccm; magnetron sputtering of the color layer is conducted at a temperature of about 50° C.-150° C. and takes about 10 min-30 min.

13. The process as claimed in claim 12, wherein the substrate has a negative bias voltage of about −100V to about −300V during sputtering the color layer.

14. The process as claimed in claim 9, wherein the color layer is a layer of titanium-carbon-nitrogen, titanium nitride, or chromium-carbon-nitrogen formed by vacuum sputtering or arc ion plating.

15. The process as claimed in claim 9, wherein the insulation layer is a layer of silicon dioxide or aluminum oxide, forming the insulation layer is by using a vacuum sputtering process, uses silicon or aluminum target, the target is applied with a power of about 5 KW-15 KW; uses oxygen as a reaction gas, the oxygen has a flow rate of about 50 sccm-150 sccm; uses argon as a working gas, the argon has a flow rate of about 100 sccm-200 sccm; vacuum sputtering of the insulation layer is conducted at a temperature of about 150° C.-250° C. and takes about 60 min-120 min.

16. The process as claimed in claim 15, wherein the substrate has a negative bias voltage of about −100V to about −300V during sputtering the insulation layer.

17. The process as claimed in claim 9, wherein the insulation layer is a layer of polytetrafluoroethylene formed by chemical vacuum deposition or spraying.

18. The process as claimed in claim 9, wherein the insulation layer is a layer of insulative paint or insulative ink formed by spraying or printing.

19. The process as claimed in claim 9, further comprising a step of pre-treating the substrate before forming the barrier layer.

20. The process as claimed in claim 19, wherein the pre-treating process comprising ultrasonic cleaning the substrate and plasma cleaning the substrate.
